(19) United States
(12) Patent Application Publication
(10) Pub. No.: US 2026/0313916 A1
(43) Pub. Date: Oct. 8, 2026

(54) SEMICONDUCTOR DEVICE WITH A CROSS-POINT STRUCTURE

(71) Applicant: SK hynix Inc., Gyeonggi-do (KR)

(72) Inventor: Kyung Wan KIM, Gyeonggi-do (KR)

(21) Appl. No.: 19/382,259

(22) Filed: Nov. 7, 2025

(30) Foreign Application Priority Data
Apr. 2, 2025 (KR) 10-2025-0042519

(51) Int. Cl. H10B 63/00

(52) U.S. Cl. CPC H10B 63/80

(57) ABSTRACT

A semiconductor device includes a local X-switch block; a first auxiliary X-switch block, aligned with and overlapping the local X-switch block in a first direction, disposed on a first row; a plurality of first cell areas, aligned with each other in the first direction, disposed on the first row between the local X-switch block and the first auxiliary X-switch block; and first X-lines extending from the local X-switch block to cross the plurality of first cell areas in the first direction. The local X-switch block includes a plurality of local X-switches aligned with each other in a second direction, which is perpendicular to the first direction. The first auxiliary X-switch block includes a first auxiliary X-switch. The first X-lines include a first outer X-line electrically connected to the first auxiliary X-switch and a first one of the plurality of local X-switches; and a first inner X-line.

### CROSS-REFERENCE TO RELATED APPLICATIONS

This patent document claims priority under 35 U.S.C. 119(a) to Korean Patent Application No. 10-2025-0042519, filed on Apr. 02, 2025, which is incorporated herein by reference in its entirety.

### TECHNICAL FIELD

Embodiments of the present disclosure relates to a semiconductor device having a cross-point structure.

### BACKGROUND

Cells of a semiconductor device having a cross-point structure may be selectively enabled by receiving a voltage or current when local switches are turned on. As the degree of integration of semiconductor devices has increased, the number of the cells that have to be enabled by one local switch has also increased.

### SUMMARY

Embodiments of the present disclosure compensate for the undercurrent of the cells according to the position in a semiconductor device.

In accordance with an embodiment of the present disclosure, a semiconductor device includes a local X-switch block; a first auxiliary X-switch block, aligned with and overlapping the local X-switch block in a first direction, disposed on a first row; a plurality of first cell areas, aligned with each other in the first direction, disposed on the first row between the local X-switch block and the first auxiliary X-switch block; and first X-lines extending from the local X-switch block to cross the plurality of first cell areas in the first direction. The local X-switch block includes a plurality of local X-switches aligned with each other in a second direction, which is perpendicular to the first direction. The first auxiliary X-switch block includes a first auxiliary X-switch. The first X-lines include a first outer X-line electrically connected to the first auxiliary X-switch and a first one of the plurality of local X-switches; and a first inner X-line electrically connected to a second one of the plurality of local X-switches and not electrically connected to the first auxiliary X-switch.

In accordance with an embodiment of the present disclosure, a semiconductor device includes a local Y-switch block; a first auxiliary Y-switch block, aligned with and overlapping a left area of the local Y-switch block in a vertical direction, arranged in a first column; a plurality of first cell areas, aligned with each other in the vertical direction, arranged in the first column between the local Y-switch block and the first auxiliary Y-switch block; and first Y-lines extending from the local Y-switch block to cross the plurality of first cell areas in the vertical direction. The local Y-switch block includes a plurality of local Y-switches aligned in a horizontal direction perpendicular to the vertical direction. The first auxiliary Y-switch block includes a first auxiliary Y-switch. The first Y-lines include a first outer Y-line electrically connected to the first auxiliary Y-switch and a first one of the plurality of local Y-switches; and a first inner Y-line electrically connected to a second one of the plurality of local Y-switches and not electrically connected to the first auxiliary Y-switch.

In accordance with an embodiment of the present disclosure, a semiconductor device includes a plurality of cell areas arranged in a matrix form, wherein the matrix form includes a plurality of rows and a plurality of columns; a first local switch block disposed between first cell areas among the plurality of cell areas in a first direction, wherein the first local switch block has a segment shape extending in a second direction; a second local switch block disposed between second cell areas among the plurality of cell areas in the second direction, wherein the second local switch block has a segment shape extending in the first direction; a first auxiliary switch block disposed between third cell areas among the plurality of cell areas in the first direction, wherein the first auxiliary switch block is aligned with the first local switch block in the second direction; and a second auxiliary switch block disposed between fourth cell areas among the plurality of cell areas in the second direction. The second auxiliary switch block is aligned with the second local switch block in the first direction. The first direction and the second direction are perpendicular to each other. The first local switch block completely overlaps the first cell areas in the first direction. The second local switch block completely overlaps the second cell areas in the second direction. The first auxiliary switch block partially overlaps the third cell areas in the first direction. The second auxiliary switch block partially overlaps the fourth cell areas in the second direction.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a block diagram illustrating a semiconductor device according to an embodiment of the present disclosure.

FIGS. 2A and 2B are block diagrams schematically illustrating cell arrays according to embodiments of the present disclosure.

FIGS. 3A and 3B are block diagrams schematically illustrating a cell array of a semiconductor device according to an embodiment of the present disclosure.

FIGS. 4A and 4B are block diagrams schematically illustrating a cell array of a semiconductor device according to an embodiment of the present disclosure.

FIGS. 5A-5C are block diagrams schematically illustrating a cell area according to an embodiment of the present disclosure.

### DETAILED DESCRIPTION

Embodiments of the present disclosure are described in detail with reference to the accompanying drawings. Specific structural or functional descriptions of specific embodiments are provided as examples to describe the technical concepts that are disclosed in the present application. However, it should be understood that various other examples or embodiments in accordance with the technical concepts of the present disclosure may be carried out in various forms by those with ordinary skill in the art without departing from the scope of the present disclosure. Hence, the present invention is not limited only to the described examples or embodiments.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

Throughout the specification, "be selected" and "be enabled" may mean that a current is provided or drawn. For example, "be selected" and "be enabled" can be interpreted as data being written or read.

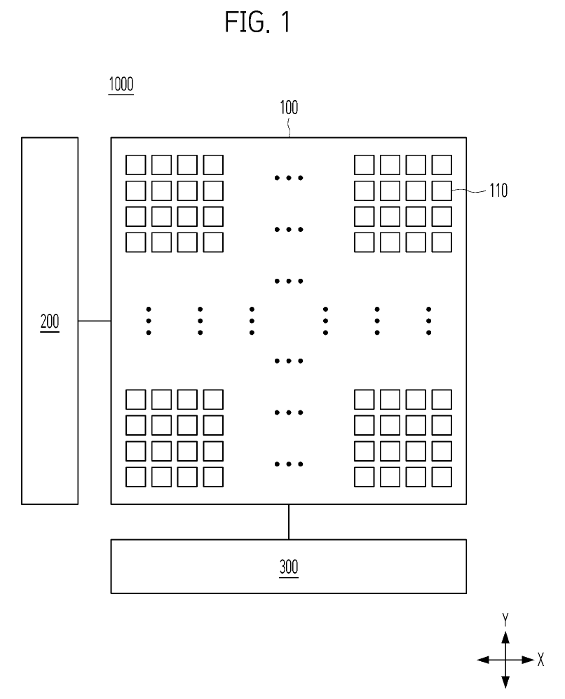

FIG. 1 is a block diagram illustrating a semiconductor device 1000 according to an embodiment of the present disclosure. Referring to FIG. 1, the semiconductor device 1000 may include a cell array 100, an X-control block 200, and a Y-control block 300. The cell array 100 may include a plurality of cell areas 110 arranged in a matrix shape. The X-control block 200 may be disposed to be electrically connected adjacent to the cell array 100 in the X-direction (X). For example, the X-control block 200 may selectively enable cells in the cell areas 110 in the cell array 100 according to an address signal. The X-control block 200 may include an address coding circuit, a word line driving circuit, and/or a global X-switching circuit. The Y-control block 300 may be disposed to be electrically connected adjacent to the cell array 100 in the Y-direction (Y). The Y-control block 300 may write data to selected cells in the cell areas 110 in the cell array 100 or read data from the selected cells in the cell areas 110 in the cell array 100. The Y-control block 300 may include an input and output (input/output) buffer circuit, a global Y-switching circuit, and/or a sense amplifier circuit.

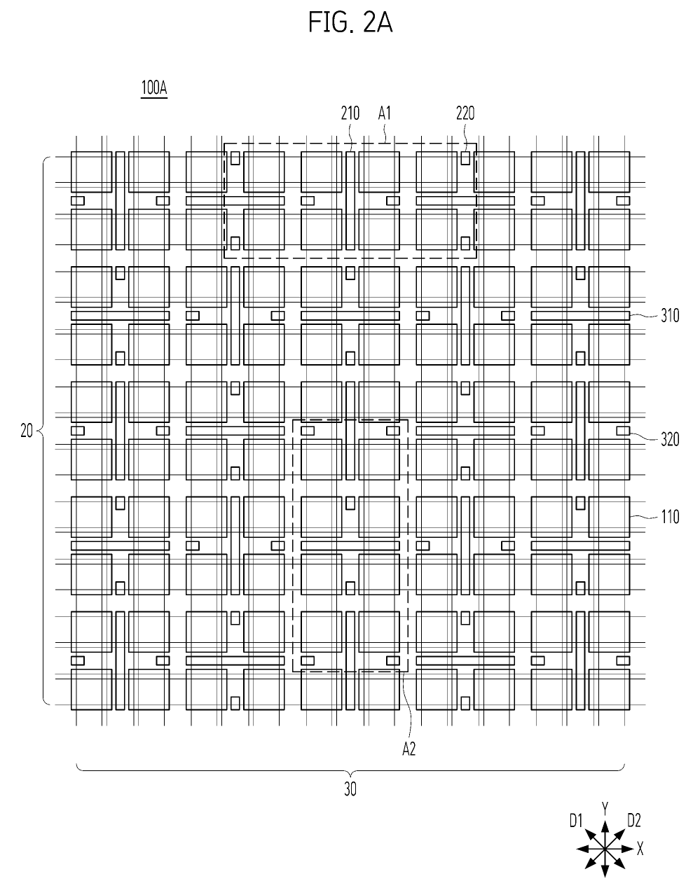

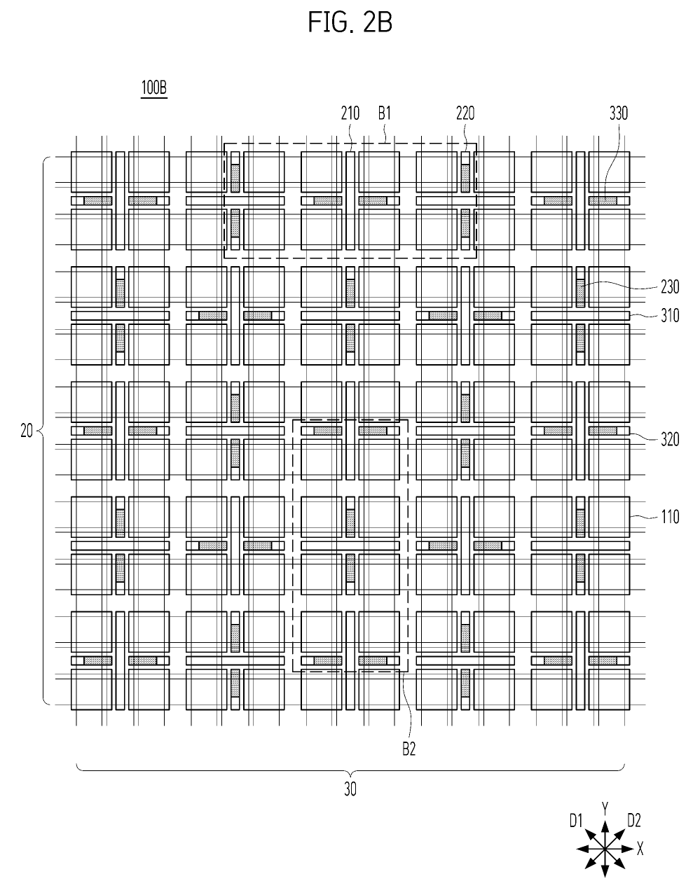

FIGS. 2A and 2B are block diagrams schematically illustrating cell arrays 100A and 100B according to embodiments of the present disclosure. Referring to FIG. 2A, the cell array 100A may include cell areas 110, local X-switch blocks 210, local Y-switch blocks 310, auxiliary X-switch blocks 220, auxiliary Y-switch blocks 320, X-lines 20, and Y-lines 30. The cell areas 110 may be arranged in a matrix form in a first direction X and a second direction Y. The first direction X and the second direction Y may be perpendicular to each other. For example, the first direction X may be a row direction and the second direction Y may be a column direction. Thus, the cell areas 110 may be arranged in a matrix form having a plurality of rows and a plurality of columns. In another embodiment, the first direction X may be the column direction and the second direction Y may be the row direction. To facilitate understanding of the technical concepts of the present disclosure, it has been illustrated that the cell areas 110 are spaced apart at regular intervals in the first direction X and the second direction Y, respectively.

The local X-switch blocks 210 may be disposed between some of the cell areas 110 adjacent to each other in the first direction X. Each of the local X-switch blocks 210 may be adjacent to at least two cell areas 110 on a left side and a right side in the first direction X, respectively. Both sides of each of the local X-switch blocks 210 may be adjacent to at least two cell areas 110, respectively. For example, at least two cell areas 110 may be disposed adjacent to the left side of each local X-switch block 210, and at least two cell areas 110 may be disposed adjacent to the right side of each local X-switch block 210. Two cell areas 110 adjacent to one side of each of the local X-switch blocks 210 may be disposed adjacent to each other in the second direction Y. Each of the local X-switch blocks 210 may have a segment shape elongated to extend in the second direction Y between the adjacent cell areas 110. In the cell array 100A, in the first direction X, the local X-switch blocks 210 may be spaced apart from each other by four cell areas 110. That is, four cell areas 110 may be arranged to be disposed between the local X-switch blocks 210 in the first direction X. In the cell array 100A, the local X-switch blocks 210 may be arranged in a zigzag form in the first direction X and the second direction Y, respectively. The local X-switch blocks 210 may be arranged to be offset by at least two cell areas 110, respectively, in the first direction X and the second direction Y. The local X-switch blocks 210 may be arranged to be aligned in first and second diagonal directions D1 and D2, respectively. The first diagonal direction D1 and the second diagonal direction D2 may intersect to each other. The first and second diagonal directions D1 and D2 may diagonally intersect the first and second directions X and Y.

The local Y-switch blocks 310 may be disposed between some of the cell areas 110 adjacent to each other in the second direction Y. Each of the local Y-switch blocks 310 may be adjacent to at least two cell areas 110 on a top side and a bottom side, respectively, in the second direction Y. The top side and the bottom side of each of the local Y-switch blocks 310 may be adjacent to at least two cell areas 110, respectively. For example, at least two cell areas 110 may be disposed adjacent to the top side of each local Y-switch block 310, and at least two cell areas 110 may be disposed adjacent to the bottom side of each local Y-switch block 310. Two cell areas 110 adjacent to the top and bottom sides of each of the local Y-switch blocks 310 may be disposed adjacent to each other in the first direction X. Each of the local Y-switch blocks 310 may have a segment shape elongated to extend in the first direction X between the plurality of adjacent cell areas 110. In the cell array 100A, in the second direction Y, the local Y-switch blocks 310 may be spaced apart from each other by four cell areas 110. That is, four cell areas 110 may be arranged to be disposed between the local Y-switch blocks 310 in the second direction Y. In the cell array 100A, the local Y-switch blocks 310 may be arranged in a zigzag form in the first direction X and the second direction Y, respectively. The local Y-switch blocks 310 may be arranged to be offset by at least two cell areas 110 in the first direction X and the second direction Y, respectively. The local Y-switch blocks 310 may be arranged to be aligned in the first and second diagonal directions D1 and D2, respectively.

The auxiliary X-switch blocks 220 may overlap and align the local X-switch blocks 210 in the first direction X. The auxiliary X-switch blocks 220 may overlap and be aligned with the local Y-switch block 310 in the second direction Y. The auxiliary X-switch blocks 220 may be disposed to be spaced apart from the local X-switch blocks 210 by at least two cell areas 110 in the first direction X. For example, in the first direction X, at least two cell areas 110 may be disposed between each of the auxiliary X-switch blocks 220 and each of the local X-switch blocks 210. The auxiliary X-switch blocks 220 may have a segment shape partially overlapping or aligned with the cell areas 110 adjacent to each other in the second direction Y. For example, two of the auxiliary X-switch blocks 220 may be paired, and a pair of auxiliary X-switch blocks 220 may be disposed to overlap or be aligned with both ends of the local X-switch blocks 210 adjacent to each other in the first direction X. A single local Y-switch block 310 may be disposed between the pair of auxiliary X-switch blocks 220. The auxiliary X-switch blocks 220 may be arranged to be aligned in the first and second diagonal directions D1 and D2, respectively. The auxiliary X-switch block 220 may be disposed to partially overlap one of the cell areas 110 in the first direction X.

The auxiliary Y-switch blocks 320 may overlap and be aligned with the local Y-switch blocks 310 in the second direction Y. The auxiliary Y-switch blocks 320 may overlap and be aligned with the local X-switch block 210 in the first direction X. The auxiliary Y-switch blocks 320 may be disposed to be spaced apart from the local Y-switch blocks 310 by at least two cell areas 110 in the second direction Y. For example, in the second direction Y, at least two cell areas 110 may be disposed between each of the auxiliary Y-switch blocks 320 and each of the local Y-switch blocks 310. Each of the auxiliary Y-switch blocks 320 may have a segment shape partially overlapping or aligned with the cell areas 110 adjacent to each other in the first direction X. For example, two of the auxiliary Y-switch blocks 320 may form a pair, and the pair of auxiliary Y-switch blocks 320 may be disposed to overlap or be aligned with both ends of the local Y-switch blocks 310 adjacent to each other in the second direction Y. A single local X-switch block 210 may be disposed between the pair of auxiliary Y-switch blocks 320. The auxiliary Y-switch blocks 320 may be arranged to be aligned in the first and second diagonal directions D1 and D2, respectively. The auxiliary Y-switch block 320 may be disposed to partially overlap one of the cell areas 110 in the second direction Y.

The local X-switch blocks 210 and the pair of the auxiliary X-switch blocks 220 may be arranged to be aligned and alternately in the first direction X and the second direction Y, respectively. The local Y-switch blocks 310 and the pair of the auxiliary Y-switch blocks 320 may be disposed to be aligned and alternately in the first direction X and the second direction Y.

The X-lines 20 may extend in parallel with each other in the first direction X to cross the cell areas 110, the local X-switch blocks 210, and the auxiliary X-switch blocks 220. The Y-lines 30 may extend in parallel with each other in the second direction Y to cross the cell areas 110, the local Y-switch blocks 310, and the auxiliary Y-switch blocks 320.

Referring to FIG. 2B, a cell array 100B may include cell areas 110, local X-switch blocks 210, local Y-switch blocks 310, auxiliary X-switch blocks 220, auxiliary Y-switch blocks 320, dummy X-switch blocks 230, and dummy Y-switch blocks 330. Compared with the cell array 100A of FIG. 2A, the cell array 100B may further include the dummy X-switch blocks 230 and the dummy Y-switch blocks 330.

A pair of dummy X-switch blocks 230 may be disposed between the pair of auxiliary X-switch blocks 220 in the second direction Y. The pair of dummy X-switch blocks 230 may overlap and be aligned with the pair of auxiliary X-switch blocks 220 adjacent to each other in the second direction Y. A single local Y-switch block 310 may be disposed between the pair of dummy X-switch blocks 230.

The pair of dummy Y-switch blocks 330 may be disposed to be aligned with each other between the pair of auxiliary Y-switch blocks 320 in the first direction X. The pair of dummy Y-switch blocks 330 may overlap and be aligned with the pair of auxiliary Y-switch blocks 320 adjacent to each other in the first direction X. A single local X-switch block 210 may be disposed between the pair of dummy Y-switch blocks 330.

The X-lines 20 may extend in parallel with each other in the first direction X to cross the cell areas 110, the local X-switch blocks 210, the auxiliary X-switch blocks 220, and the dummy X-switch blocks 230. The Y-lines 30 may extend in parallel with each other in the second direction Y to cross the cell areas 110, the local Y-switch blocks 310, the auxiliary Y-switch blocks 320, and the dummy Y-switch blocks 330.

All the cell areas 110 may not be disposed adjacent (for example, coincident, co-located) to both the local X-switch blocks 210 and the local Y-switch blocks 310. For example, the cell areas 110 adjacent to the local X-switch blocks 210 in the first direction X may be spaced apart from the local Y-switch blocks 310 in the second direction Y by at least one cell area 110. In addition, the cell areas 110 adjacent to the local Y-switch blocks 310 in the second direction Y may be spaced apart from the local Y-switch blocks 310 in the first direction X by at least one cell area 110.

According to the embodiments, the cell areas 110 may not be disposed adjacent to both the local X-switch blocks 210 and the local Y-switch blocks 310. For example, each of the cell areas 110 may be disposed adjacent to only one of the local X-switch blocks 210 and the local Y-switch blocks 310. Therefore, a near-cell effect caused by overcurrent that may occur when the cell areas 110 are disposed adjacent to both the local X-switch blocks 210 and the local Y-switch blocks 310 can be prevented or mitigated.

According to the embodiments, the cell areas 110 may be disposed juxtapositionally not far from both (for example, based on the near-cell effect and/or a relative distance between each of) the local X-switch blocks 210 and the local Y-switch blocks 310. The cell areas 110 disposed far from both the local X-switch blocks 210 and the local Y-switch block 310 may be disposed adjacent to one of the auxiliary X-switch blocks 220 or one of the auxiliary Y-switch blocks 320. Accordingly, a far-cell effect caused by the low current that can occur when the cell areas 110 are disposed co-locatedly far from both the local X-switch blocks 210 and the local Y-switch blocks 310 can be prevented or mitigated.

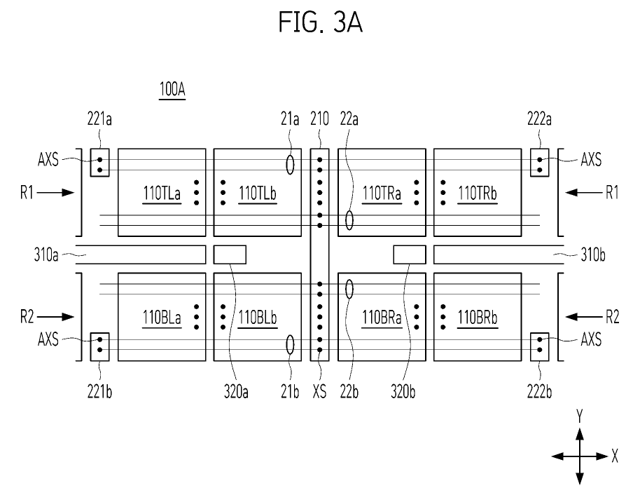

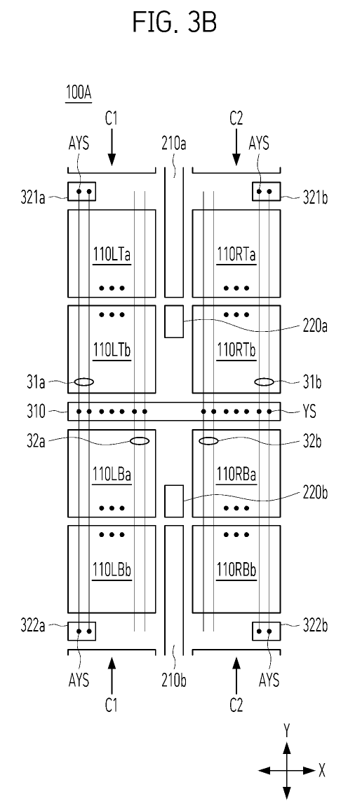

FIGS. 3A and 3B are block diagrams schematically illustrating a cell array 100A of a semiconductor device according to an embodiment of the present disclosure. FIG. 3A is an enlarged block diagram of the area A1 of FIGS. 2A, and 3B is an enlarged block diagram of the area A2 of FIG. 2A. FIG. 3A illustrates an arrangement and electrical connections of the X-lines 20: 21a, 21b, 22a, and 22b and the auxiliary X-switch blocks 220: 221a, 221b, 222a, and 222b, and FIG. 3B illustrates an arrangement and electrical connections of the Y-lines 30: 31a, 31b, 32a, and 32b and the auxiliary Y-switch blocks 320: 321a, 321b, 322a, and 322b. In FIG. 3A, the Y-lines 30: 31a, 31b, 32a, 32b are omitted, and in FIG. 3B, the X-lines 20: 21a, 21b, 22a, 22b are omitted. FIGS. 3A and 3B illustrate (different aspects of) the same embodiment.

Referring to FIG. 3A, the cell array 100A may include the cell areas 110TLa, 110TLb, 110TRa, 110TRb, 110BLa, 110BLb, 110BRa, and 110BRb, the local X-switch blocks 210, the local Y-switch blocks 310a and 310b, the auxiliary X-switch blocks 221a, 221b, 222a and 222b, the auxiliary Y-switch blocks 320a and 320b, and the X-lines 21a, 21b, 22a and 22b.

The cell areas 110TLa, 110TLb, 110TRa, 110TRb, 110BLa, 110BLb, 110BRa, and 110BRb may include upper cell areas 110TLa, 110TLb, 110TRa, and 110TRb arranged side-by-side to be aligned with each other on a first row R1 (upper row) in the first direction X and lower cell areas 110BLa, 110BLb, 110BRa, and 110BRb arranged side-by-side to be aligned with each other on a second row R2 (lower row). The local Y-switch blocks 310a and 310b and the auxiliary Y-switch blocks 320a and 320b may be disposed between the upper cell areas 110TLa, 110TLb, 110TRa, and 110TRb and the lower cell areas 110BLa, 110BLb, 110BRa, and 110BRb in the second direction. For example, the upper cell areas 110TLa, 110TLb, 110TRa, and 110TRb arranged in the first row R1 may be disposed in upper regions of the local Y-switch blocks 310a and 310b and the auxiliary Y-switch blocks 320a and 320b, and the lower cell areas 110BLa, 110BLb, 110BRa, and 110BRb arranged in the second row R2 may be disposed in lower regions of the local Y-switch blocks 310a and 310b and the auxiliary Y-switch blocks 320a and 320b. The upper cell areas 110TLa, 110TLb, 110TRa, and 110TRb may include first upper outer and inner cell areas 110TLa and 110TLb disposed on a left side of the local X-switch block 210 and second upper inner and outer cell areas 110TRa and 110TRb disposed on a right side of the local X-switch block 210. The lower cell areas 110BLa, 110BLb, 110BRa, and 110BRb may include first lower outer and inner cell areas 110BLa and 110BLb disposed on the left side of the local X-switch block 210 and second lower inner and outer cell areas 110BRa and 110BRb disposed on the right side of the local X-switch block 210.

The local X-switch block 210 may be disposed between the first upper inner cell area 110TLb and the second upper inner cell areas 110TRa arranged on the first row R1, and between the first lower inner cell area 110BLb and the second lower inner cell area 110BRa arranged on the second row R2, in the first direction X. The local X-switch block 210 may completely overlap the cell areas 110TLa, 110TLb, 110TRa, 110TRb110BLa, 110BLb, 110BRa, and 110BRb in the first direction X. The first row R1 may cross the upper region of the local X-switch block 210 in the first direction X, and the second row R2 may cross the lower region of the local X-switch block 210 in the first direction X. The local X-switch block 210 may have a segment shape extending in the second direction Y. The local X-switch block 210 may include a plurality of local X-switches XS aligned and disposed in the second direction Y. In an embodiment, the plurality of local X-switches XS may include local X-transistors.

The auxiliary X-switch blocks 221a, 221b, 222a, and 222b may be disposed in outer regions at both left and right ends of the cell areas 110TLa, 110TLb, 110TRa, 110TRb, 110BLa, 110BLb, 110BRa, and 110BRb controlled by the local X-switch block 210 in the first direction X. For example, the auxiliary X-switch blocks 221a, 221b, 222a and 222b may be disposed in outer regions of the outer cell areas 110TLa, 110TRb, 110BLa and 110BRb located farthest from the local X-switch block 210 in the first direction X, respectively. The auxiliary X-switch blocks 221a, 221b, 222a and 222b may include a first upper auxiliary X-switch block 221a disposed in an upper region of a left outer region of the first upper outer cell area 110TLa, a first lower auxiliary X-switch block 221b disposed in a lower region of a left outer region of the first lower outer cell area 110BLa, a second upper auxiliary X-switch block 222a disposed in an upper region of a right outer region of the second upper outer cell area 110TRb, and a second lower auxiliary X-switch block 222b disposed in a lower region of a right outer region of the second lower outer cell area 110BRb. The first and second upper auxiliary X-switch blocks 221a and 222a may be disposed to partially overlap the upper cell areas 110TLa, 110TLb, 110TRa and 110TRb in the first direction X. The first and second lower auxiliary X-switch blocks 221b and 222b may be disposed to partially overlap the lower cell areas 110BLa, 110BLb, 110BRa and 110BRb in the first direction X. Each of the auxiliary X-switch blocks 221a, 221b, 222a and 222b may include a plurality of auxiliary X-switches AXS aligned and disposed in the second direction Y. In an embodiment, the plurality of auxiliary X-switches AXS may include auxiliary X-transistors. An occupied area of each of the auxiliary X-switch blocks 221a, 221b, 222a, and 222b may be smaller than an occupied area of the local X-switch block 210. Therefore, the number of the auxiliary X-switches AXS arranged in each of the auxiliary X-switch blocks 221a, 221b, 222a, and 222b may be less than the number of the local X-switch XS arranged in the local X-switch block 210.

The local Y-switch blocks 310a and 310b and the auxiliary Y-switch blocks 320a and 320b may be disposed between the upper cell areas 110TLa, 110TLb, 110TRa, and 110TRb arranged on the first row R1 and the lower cell areas 110BLa, 110BLb, 110BRa, and 110BRb arranged on the second row R2. For example, each of the local Y-switch blocks 310a and 310b may be disposed between the first and second upper outer cell areas 110TLa and 110TRb and the first and second lower cell areas 110BLa and 110BRb disposed at both left and right ends, far from (for example, separated by more than an area occupied by (or length, distance across) the cell areas) the local X-switch block 210. The local Y-switch blocks 310a and 310b may include a first local Y-switch block 310a disposed between the first upper outer cell area 110TLa and the first lower outer cell area 110BLa, and a second local Y-switch block 310b disposed between the second upper outer cell area 110TRb and the second lower outer cell area 110BRb. In the second direction Y, the first local Y-switch block 310a may be disposed to completely overlap the first upper and lower outer cell areas 110TLa and 110BLa, and the second local Y-switch block 310b may be disposed to completely overlap the second upper and lower outer cell areas 110TRb and 110BRb. At the left end and the right end of the drawing, the local Y-switch block 310a and the second local Y-switch block 310b adjacent to each other in the first direction X may be integrated.

The auxiliary Y-switch blocks 320a and 320b may be disposed between the first and second upper inner cell areas 110TLb and 110TRa and between the first and second lower inner cell areas 110BLb and 110BRa to be close to (for example, separated by less than an area occupied by (or length, distance across) the cell areas) the local X-switch block 210 at a middle region, respectively. The auxiliary Y-switch blocks 320a and 320b may include a first auxiliary Y-switch block 320a disposed between the first upper inner cell area 110TLb and the first lower inner cell area 110BLb, and a second auxiliary Y-switch block 320b disposed between the second upper inner cell area 110TRb and the second lower inner cell area 110BRa. The first auxiliary Y-switch block 320a may be disposed to partially overlap the first upper and lower inner cell areas 110TLb and 110BLb, and the second auxiliary Y-switch block 320b may be disposed to partially overlap the second upper and lower inner cell areas 110TRa and 110BRa.

The X-lines 21a, 21b, 22a, and 22b may extend in the first direction X from the local X-switch block 210 at a central region and may cross the plurality of cell areas 110TLa, 110TLb, 110TRa, 110TRb, 110BLa, 110BLb, 110BRa, and 110BRb, respectively. In the drawing, the X-lines 21a, 21b, 22a, and 22b may cross the four cell areas 110TLa, 110TLb, 110TRa, 110TRb, 110BLa, 110BLb, 110BRa, and 110BRb, respectively, on both directions. That is, the X-lines 21a, 21b, 22a, and 22b may each cross two cell areas 110TLa, 110TLb, 110BLa, and 110BLb in one direction (left direction) and two cell areas 110TRa, 110TRb, 110BRa, and 110BRb in the other direction (right direction). The X-lines 21a, 21b, 22a, and 22b may be electrically connected to the local X-switches in the local X-switch block 210 at the central region and the cells in the cell areas 110TLa, 110TLb, 110TRa, 110TRb, 110BLa, 110BLb, 110BRa, and 110BRb, respectively. The local X-switches may be aligned in the second direction Y in the local X-switch block 210. That is, the X-lines 21a, 21b, 22a, and 22b may provide voltage or current to the cells in each of the four cell areas 110TLa, 110TLb, 110TRa, 110TRb, 110BLa, 110BLb, 110BRa, and 110BRb in both directions by the local X-switches in the local X-switch block 210 at the central region.

The X-lines 21a, 21b, 22a, and 22b may include outer X-lines 21a and 21b and inner X-lines 22a and 22b extending parallel to each other in the first direction X. The outer and inner X-lines 21a, 21b, 22a, and 22b may include upper outer X-lines 21a, upper inner X-lines 22a, lower outer X-lines 21b, and lower inner X-lines 22b. The local Y-switch blocks 310a and 310b and the auxiliary Y-switch blocks 320a and 320b may be disposed between the upper outer and upper inner X-lines 21a and 22a and the lower outer and lower inner X-lines 21b and 22b. The upper outer and upper inner X-lines 21a and 22a may be disposed in an upper region of the local Y-switch blocks 310a and 310b and the auxiliary Y-switch blocks 320a and 320b to cross the upper cell areas 110TLa, 110TLb, 110TRa, and 110TRb on the first row R1 in the first direction X, and the lower outer and lower inner X-lines 21b and 22b may be disposed in a lower region of the local Y-switch blocks 310a and 310b and the auxiliary Y-switch blocks 320a and 320b to cross the lower cell areas 110BLa, 110BLb, 110BRa, and 110BRb on the second row R2 in the first direction X.

The outer X-lines 21a and 21b may be disposed to be spaced apart far from the local Y-switch blocks 310a and 310b and the auxiliary Y-switch blocks 320a and 320b in the second direction Y, respectively. The upper outer X-lines 21a may be disposed close to an upper end of the local X-switch block 210 and upper ends of the upper cell areas 110TLa, 110TLb, 110TRa, and 110TRb on the first row R1, and the lower outer X-lines 21b may be disposed close to a lower end of the local X-switch block 210 and lower ends of the lower cell areas 110BLa, 110BLb, 110BRa, and 110BRb on the second row R2. Thus, the upper outer X-lines 21a may cross an upper region of the local X-switch block 210 and upper regions of the upper cell areas 110TLa, 110TLb, 110TRa, and 110TRb on the first row R1, and the lower outer X-lines 21b may cross a lower region of the local X-switch block 210 and lower regions of the lower cell areas 110BLa, 110BLb, 110BRa, and 110BRb on the second row R2. Each of the outer X-lines 21a and 21b may electrically connect the local X-switches in the local X-switch block 210 disposed in the first direction X to the auxiliary X-switches in the auxiliary X-switch blocks 221a, 221b, 222a, and 222b disposed on the same horizontal line. The outer X-lines 21a and 21b may be electrically connected to the cells in the cell areas 110TLa, 110TLb, 110TRa, 110TRb, 110BLa, 110BLb, 110BRa, and 110BRb disposed on the same horizontal line, respectively. That is, the local X-switch, the cells, the auxiliary X-switch, and corresponding one of the outer X-lines 21a and 21b disposed on the same horizontal line may be electrically connected to each other.

The inner X-lines 22a and 22b may be disposed adjacent to close to or not far from the local Y-switch blocks 310a and 310b and the auxiliary Y-switch blocks 320a and 320b in the second direction Y, respectively. The upper inner X-lines 22a may be disposed close to a middle-upper region of the local X-switch block 210 and the lower ends of the upper cell areas 110TLa, 110TLb, 110TRa, and 110TRb on the first row R1. The lower inner X-lines 22b may be disposed close to a middle-lower region of the local X-switch block 210 and the upper ends of the lower cell areas 110BLa, 110BLb, 110BRa, and 110BRb on the second row R2. Thus, the upper inner X-lines 22a may cross the middle-upper region of the local X-switch block 210 and the lower regions of the upper cell areas 110TLa, 110TLb, 110TRa, and 110TRb on the first row R1, and the lower inner X-lines 22b may cross the middle-lower region of the local X-switch block 210 and the upper regions of the lower cell areas 110BLa, 110BLb, 110BRa, and 110BRb on the second row R2. The inner X-lines 22a and 22b may be electrically connected to the local X-switches in the local X-switch block 210 and the cells in the cell areas 110TLa, 110TLb, 110TRa, 110TRb, 110BLa, 110BLb, 110BRa, and 110BRb disposed on the same horizontal line in the first direction X. That is, the local X-switch, the cells, and corresponding one of the inner X-lines 22a and 22b disposed on the same horizontal line may be electrically connected to each other.

The upper outer X-lines 21a and the lower outer X-lines 21b may be electrically connected to both the local X-switches in the local X-switch block 210 and the auxiliary X-switches in the auxiliary X-switch blocks 221a, 221b, 222a, and 222b, respectively. The auxiliary X-switches may be aligned in the second direction Y in the auxiliary X-switch blocks 221a, 221b, 222a, and 222b, respectively. Each of the local X-switches in the local X-switch block 210 and the auxiliary X-switches in each of the auxiliary X-switch blocks 221a, 221b, 222a, and 222b connected to each of the upper outer X-lines 21a and each of the lower outer X-lines 21b may be activated at the same time.

Thus, each of the upper outer X-lines 21a and the lower outer X-lines 21b may be selectively enabled by simultaneously providing a voltage or current to the cells in the cell areas 110TLa, 110TLb, 110TRa, 110TRb, 110BLa, 110BLb, 110BRa, and 110BRb from the central local X-switch block 210, and the auxiliary X-switch blocks 221a, 222b, 222a, and 222b.

The inner X-lines 22a and 22b may not be electrically connected to the auxiliary X-switch blocks 221a, 221b, 222a and 222b. That is, the inner X-lines 22a and 22b may selectively be enabled by providing a voltage or current to cells in the cell areas 110TLa, 110TLb, 110TRa, 110TRb, 110BLa, 110BLb, 110BRa, and 110BRb from the local X-switch block 210 at the central region.

Referring to FIG. 3B, a cell array 100B of the semiconductor device may include cell areas 110LTa, 110LTb, 110RTa, 110RTb, 110LBa, 110LBb, 110RBa, and 110RBb, local X-switch blocks 210a and 210b, local Y-switch blocks 310, auxiliary X-switch blocks 220a and 220b, auxiliary Y-switch blocks 321a, 321b, 322a, and 322b, and Y-lines 31a, 31b, 32a, and 32b.

The cell areas 110LTa, 110LTb, 110LBa, 110LBb, 110RTa, 110RTb, 110RBa, and 110RBb may include left cell areas 110LTa, 110RTb, 110LBa, and 110LBb disposed on a first column C1 (left column) and right cell areas 110RTa, 110RTb, 110RBa, and 110RBb disposed on a second column C2 (right column) in the second direction Y. The local X-switch blocks 210a and 210b and the auxiliary X-switch blocks 220a and 220b may be disposed between the left cell areas 110LTa, 110LTb, 110LBa, and 110LBb and the right cell areas 110RTa, 110RTb, 110RBa, and 110RBb. For example, the left cell areas 110LTa, 110LTb, 110LBa, and 110LBb disposed in the first column C1 may be disposed in a left region of the local X-switch blocks 210a and 210b and the auxiliary X-switch blocks 220a and 220b, and the right cell areas 110RTa, 110RTb, 110RBa, and 110RBb disposed in the second column C2 may be disposed in a right region of the local X-switch blocks 210a and 210b and the auxiliary X-switch blocks 220a and 220b. The left cell areas 110LTa, 110LTb, 110LBa, and 110LBb may include first left upper and lower cell areas 110LTa and 110LTb disposed in an upper region of the local Y-switch block 310 and second left upper and lower cell areas 110LBa and 110LBb disposed in a lower region of the local Y-switch block 310. The right cell areas 110RTa, 110RTb, 110RBa, and 110RBb may include first right upper and lower cell areas 110RTa and 110RTb disposed in the upper region of the local Y-switch block 310 and second right upper and lower cell areas 110RBa and 110RBb disposed in the lower region of the local Y-switch block 310.

The local X-switch blocks 210a and 210b and the auxiliary X-switch blocks 220a and 220b may be disposed between the left cell areas 110LTa, 110LTb, 110LRa, and 110LRb arranged in the first column C1 and the right cell areas 110RTa, 110RTb, 110RBa, and 110RBb arranged in the second column C2. The local X-switch blocks 210a and 210b may include a first local X-switch block 210a and a second local X-switch block 210b. The first local X-switch block 210a may be disposed between the first left upper cell areas 110LTa and the first right upper cell area 110RTa disposed at upper ends far from the local Y-switch block 310, and the second local X-switch block 210b may be disposed between the second left lower cell area 110LBb and the second right lower cell area 110RBb disposed at lower ends far from the local Y-switch block 310.

The auxiliary X-switch blocks 220a and 220b may include a first auxiliary X-switch block 220a disposed between the first left lower cell areas 110LTb and the first right lower cell area 110RTb to be close to the local Y-switch block 310, and a second auxiliary X-switch block 220b disposed between the second left upper cell area 110LBa and the second upper cell area 110RBa to be close to the local Y-switch block 310. In the first direction X, the first auxiliary X-switch block 220a may partially overlap the first left lower cell area 110LTb and the first right lower cell area 110RTb, and the second auxiliary X-switch block 2209b may partially overlap the second left upper cell area 110LBa and the second right upper cell area 110RBa.

In the second direction Y, the local Y-switch block 310 may be disposed between the first and second left cell areas 110LTa, 110LTb, 110LBa, and 110LBb disposed on the first column C1 and between the first and second right cell areas 110RTa, 110RTb, 110RBa, and 110RBb arranged on the second column C2. The first column C1 may cross a left region of the local Y-switch block 310 in the second direction Y, and the second column C2 may cross a right region of the local Y-switch block 310 in the second direction Y. The local Y-switch block 310 may have a segment shape extending in the first direction X. The local Y-switch block 310 may be disposed to completely overlap the cell areas 110LTa, 110LTb, 110LBa, 110LBb, 110RTa, 110RTb, 110RBa and 110RBb in the second direction Y. The local Y-switch block 310 may include a plurality of local Y-switches YS aligned and disposed in the first direction X. In an embodiment, the plurality of local Y-switches YS may include local Y-transistors.

The auxiliary Y-switch blocks 321a, 321b, 322a, and 322b may be disposed in outer regions at an upper end and a lower end of the cell areas 110LTa, 110LTb, 110LBa, 110LBb, 110RTa, 110RTb, 110RBa, and 110RBb, respectively, controlled by the local Y-switch block 310 in the second direction Y. For example, the auxiliary Y-switch blocks 321a, 321b, 322a, and 322b may be disposed in the upper/lower outer areas of the upper/lower cell areas 110LTa, 110LBb, 110RTa, and 110RBb located farthest in the second direction Y, respectively. The auxiliary Y-switch blocks 321a, 321b, 322a, and 322b may include a first left auxiliary Y-switch block 321a disposed in a left region of the upper outer region of the first left upper cell area 110LTa, a first right auxiliary Y-switch block 321b disposed in a right region of the upper outer region of the first right upper cell area 110RTa, a second left auxiliary Y-switch block 322a disposed in a left region of the lower outer region of the second left lower cell area 110LBb, and a second right auxiliary Y-switch block 322b disposed in a right region of the lower outer region of the second right lower cell area 110RBb. The first and second left auxiliary Y-switch blocks 321a and 322a may be disposed to partially overlap the first left upper and lower cell areas 110LTa and 110LTb and the second left upper and lower cell areas 110LBa and 110LBb in the second direction Y. The first and second right auxiliary Y-switch blocks 321b and 322b may be disposed to partially overlap the first right upper and lower cell areas 110RTa and 110RTb and the second right upper and lower cell areas 110RBa and 110RBb in the second direction Y. Each of the auxiliary Y-switch blocks 321a, 321b, 322a and 322b may include a plurality of auxiliary Y-switches AYS aligned in the first direction X. In an embodiment, the auxiliary Y-switches AYS may include auxiliary Y-transistors, respectively. An occupied area of each of the auxiliary Y-switch blocks 321a, 321b, 322a, and 322b may be smaller than an occupied area of the local Y-switch block 310. Therefore, the number of auxiliary Y-switches AYS disposed in each of the auxiliary Y-switch blocks 321a, 321b, 322a, and 322b may be less than the number of local Y-switches YS disposed in the local Y-switch block 310.

The Y-lines 31a, 31b, 32a, and 32b may extend in the second direction Y from the local Y-switch block 310 at the central region and may cross a plurality of cell areas 110LTa, 110LTb, 110LBa, 110LBb, 110RTa, 110RTb, 110RBa, and 110RBb, respectively. As illustrated in FIG. 3B, the Y-lines 31a, 31b, 32a, and 32b may cross four cell areas 110LTa, 110LTb, 110LBa, 110LBb, 110RTa, 110RTb, 110RBa, and 110RBb, respectively, in the second direction Y. That is, the Y-lines 31a, 31b, 32a, and 32b may each cross two cell areas 110LTa, 110LTb, 110RTa, and 110RTb in one direction (upward direction) and two cell areas 110LBa, 110LBb, 110RBa, and 110RBb in the other direction (downward direction). The Y-lines 31a, 31b, 32a, and 32b may be electrically connected to the local Y-switches in the local Y-switch block 310 and the cells in the cell areas 110LTa, 110LTb, 110LBa, 110LBb, 110RTa, 110RTb, 110RBa and 110RBb, respectively. The local Y-switches may be aligned in the first direction X in the local Y-switch block 310. That is, the Y-lines 31a, 31b, 32a, and 32b may provide a voltage or current to the cells in each of the four cell areas 110LTa, 110LTb, 110LBa, 110LBb, 110RTa, 110RTb, 110RBa, and 110RBb in the vertical direction by the local Y-switches in the local Y-switch block 310.

The Y-lines 31a, 31b, 32a, and 32b may include outer Y-lines 31a and 31b and inner Y-lines 32a and 32b extending parallel to each other in the second direction Y. The outer and inner Y-lines 21a, 21b, 22a, and 22b may include left outer X-lines 31a, left inner X-lines 32a, right outer X-lines 31b, and right inner X-lines 32b. The local X-switch blocks 210a and 210b and the auxiliary X-switch blocks 220a and 220b may be disposed between the left outer and the left inner Y-lines 31a and 32a and the right outer and the right inner Y-lines 31b and 32b. The left outer and the left inner Y-lines 31a and 32a may be disposed in left regions of the local X-switch blocks 210a and 210b and the auxiliary X-switch blocks 220a and 220b to cross the left cell areas 110LTa, 110LTb, 110LBa, and 110LBb on the first column C1 in the second direction Y, and the right outer and the right inner Y-lines 31b and 32b may be disposed in right regions of the local X-switch blocks 210a and 210b and the auxiliary X-switch blocks 220a and 220b to cross the right cell areas 110RTa, 110RTb, 110RBa, and 110RBb on the second column C2 in the second direction Y.

The outer Y-lines 31a and 31b may be disposed far from the local X-switch blocks 210a and 210b and the auxiliary X-switch blocks 220a and 220b in the first direction X, respectively (for example, separated by more than half of an area occupied by (or length, distance across) the cell areas). The left outer Y-lines 31a may be disposed close to a left end of the local Y-switch block 310 and left ends of the left cell areas 110LTa, 110LTb, 110LBa, and 110LBb on the first column C1, and the right outer Y-lines 31b may be disposed close to a right end of the local Y-switch block 310 and right ends of the right cell areas 110RTa, 110RTb, 110RBa, and 110RBb on the second column C2. Thus, the left outer Y-lines 31a may cross the left region of the local Y-switch block 310 and the left regions of the left cell areas 110LTa, 110LTb, 110LBa, and 110LBb on the first column C1, and the right outer X-lines 31b may cross the right region of the local Y-switch block 310 and the right regions of the right cell areas 110RTa, 110RTb, 110RTa, and 110RTb on the second column C2. The outer Y-lines 31a and 31b may electrically connect the local Y-switches in the local Y-switch block 310 to the auxiliary Y-switches in the auxiliary Y-switch blocks 321a, 321b, 322a, and 322b disposed on the same vertical line in the second direction Y, respectively. The outer Y-lines 31a and 31b may be electrically connected to the cells in the cell areas 110LTa, 110LTb, 110LBa, 110LBb, 110RTa, 110RTb, 110RBa, and 110RBb disposed on the same vertical line, respectively. That is, the local Y-switch, the cells, the auxiliary Y-switch, and corresponding one of the outer Y-lines 31a and 31b disposed on the same vertical line may be electrically connected to each other.

The inner Y-lines 32a and 32b may be disposed close to or not far from the local X-switch blocks 210a and 210b and the auxiliary X-switch blocks 220a and 220b in the first direction X, respectively (for example, separated by less than half of an area occupied by (or length, distance across) the cell areas). The left inner X-lines 32a may be disposed close to a middle-left region of the local Y-switch block 310 and to a right region of the left cell areas 110LTa, 110LTb, 110LBa, and 110LBb on the first column C1, and the right inner Y-lines 32b may be disposed close to a middle-right region of the local Y-switch block 310 and to a left region of the right cell areas 110RTa, 110RTb, 110RBa, and 110RBb on the second column C2. Thus, the left inner Y-lines 32a may cross the middle-left region of the local Y-switch block 310 and the right region of the left cell areas 110LTa, 110LTb, 110LBa, and 110LBb on the first column C1, and the left inner Y-lines 32b may cross the middle-right region of the local Y-switch block 310 and the left region of the right cell areas 110RTa, 110RTb, 110RBa, and 110RBb on the second column C2. The inner Y-lines 32a and 32b may be electrically connected to the local Y-switches in the local Y-switch block 310 disposed on the same vertical line in the second direction Y and the cells in the cell areas 110LTa, 110LTb, 110LBa, 110LBb, 110RTa, 110RTb, 110RBa, and 110RBb, respectively. That is, the local Y-switch, the cells, and corresponding one of the inner Y-lines 32a and 32b disposed on the same vertical line may be electrically connected to each other.

The left outer Y-lines 31a and the right outer Y-lines 31b may be electrically connected to both the local Y-switches in the local Y-switch block 310 and the auxiliary Y-switches in the auxiliary Y-switch blocks 321a, 321b, 322a, and 322b, respectively. The auxiliary Y-switches may be aligned in the first direction X in the auxiliary Y-switch blocks 321a, 321b, 322a, and 322b, respectively. Each of the local Y-switches in the local Y-switch block 310 electrically connected to each of the left outer Y-lines 31a and each of the right outer Y-lines 31b and each of the auxiliary Y-switches in each of the auxiliary Y-switch block 321a, 321b, 322a, and 322b may be simultaneously activated. Thus, each of the left outer Y-lines 31a and the right outer Y-lines 31b may be enabled selectively by simultaneously providing a voltage or current to the cells in the cell areas 110LTa, 110LTb, 110LBa, 110LBb, 110RTa, 110RTb, 110RBa, and 110RBb from the local Y-switch block 310 and the auxiliary Y-switch blocks 321a, 321b, 322a, and 322b.

The inner Y-lines 32a and 32b may not be electrically connected to the auxiliary Y-switch blocks 321a, 321b, 322a and 322b. That is, the inner Y-lines 32a and 32b may be enabled selectively by providing a voltage or current to the cells in the cell areas 110LTa, 110LTb, 110LBa, 110LBb, 110RTa, 110RTb, 110RBa, and 110RBb from the local Y-switch block 310.

Cells disposed far (or further away) from the local X-switch blocks 210a and 210b and/or the local Y-switch blocks 310a and 310b may be provided with a lower voltage or current than other cells. According to the embodiment, the cells disposed far from the local X-switch blocks 210, 210a, and 210b and/or the local Y-switch blocks 310, 310a, and 310b may receive additional voltage or current from the auxiliary Y-switches in auxiliary X-switch blocks 220, 220a, 220b, 221a, 221b, 222a, and 222b and the auxiliary Y-switch blocks 320, 320a, 320b, 321b, 321b, 322a, and 322b. Therefore, the cells disposed far from the local X-switch blocks 210: 210a and 210b and/or the local Y-switch blocks 310: 310a and 310b may exhibit as good operating characteristics as other cells.

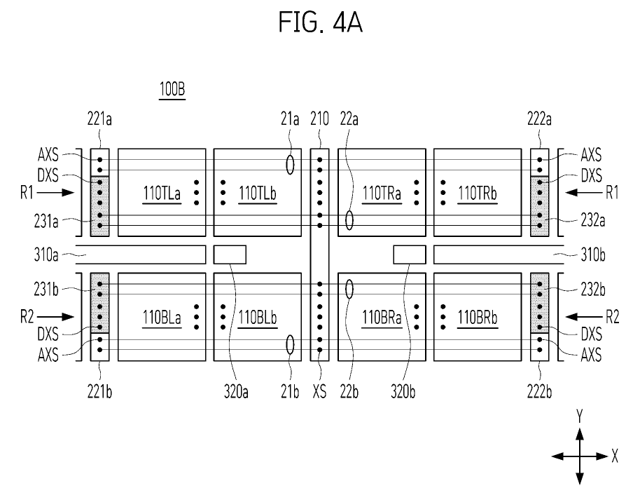

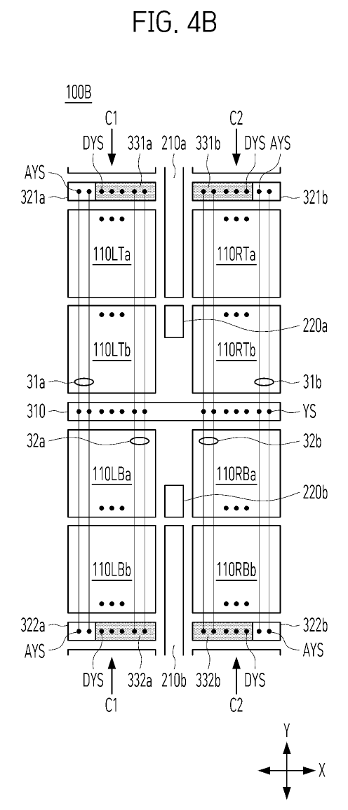

FIGS. 4A and 4B are block diagrams schematically illustrating a cell array 100B of a semiconductor device according to an embodiment of the present disclosure. FIG. 4A is an enlarged block diagram illustrating the area B1 of FIGS. 2B, and 4B is an enlarged block diagram illustrating the area B2 of FIG. 2B. In FIG. 4A, the Y-lines 30: 31a, 31b, 32a, and 32b are omitted, and in FIG. 4B, the X-lines 20: 21a, 21b, 22a, and 22b are omitted. FIGS. 4A and 4B illustrate the same embodiment.

Referring to FIG. 4A, the cell array 100B may include cell areas 110TLa, 110TLb, 110TRa, 110TRb, 110BLa, 110BLb, 110BRa, and 110BRb, a local X-switch block 210, local Y-switch blocks 310a and 310b, auxiliary X-switch blocks 221a, 221b, 222a, and 222b, auxiliary Y-switch blocks 320a and 320b, X-lines 21a, 21b, 22a, and 22b, and dummy X-switch blocks 231a, 231b, 232a, and 232b. The dummy X-switch blocks 231a, 231b, 232a, and 232b may be disposed in outer regions at both left and right ends of the cell blocks 110TLa, 110TLb, 110TRa, 110TRb, 110BLa, 110LBb, 110BRa, and 110BRb in the first direction X. The dummy X-switch blocks 231a, 231b, 232a and 232b may include a first upper dummy X-switch block 231a disposed in a left outer region of the first upper cell upper area 110TLa on a first row R1, a first lower dummy X-switch block 231b disposed in a left outer region of the first lower outer cell area 110BLa on a second row R2, a second upper dummy X-switch block 232a disposed in a right outer region of the second upper outer cell area 110TRb on the first row R1, and a second lower dummy X-switch block 232b disposed in a right outer region of the second lower outer cell area 110BRb on the second row R2. Each of the dummy X-switch blocks 231a, 231b, 232a, and 232b may include a plurality of dummy X-switches DXS aligned and disposed in the second direction Y. In an embodiment, the dummy X-switches DXS may include dummy X-transistors. In an embodiment, the dummy X-switches DXS may be electrically connected to the inner X-lines 22a and 22b. The dummy X-switches DXS may be electrically floated. In another embodiment, the dummy X-switches DXS may not be electrically connected to the inner X-lines 22a and 22b. The auxiliary X-switches AXS may provide a voltage or a current to the outer X-lines 21a and 21b. The dummy X-switches DXS may not provide a voltage or a current to the inner X-lines 22a and 22b.

Referring to FIG. 4B, the cell array 100B may include the cell areas 110LTa, 110LTb, 110LBa, 110LBb, 110RTa, 110RTb, 110RBa, and 110RBb, the local X-switch blocks 210a and 210b, the auxiliary X-switch blocks 220a and 220b, local Y-switch blocks 310, auxiliary Y-switch blocks 321a, 321b, 322a, and 322b, Y-lines 31a, 31b, 32a, and 32b, and dummy Y-switch blocks 331a, 331b, 332a, and 332b. The dummy Y-switch blocks 331a, 331b, 332a, and 332b may be disposed in outer regions at both upper and lower ends of the cell blocks 110LTa, 110LTb, 110LBa, 110LBb, 110RTa, 110RTb, 110RBa, and 110RBb in the second direction Y. The dummy Y-switch blocks 331a, 331b, 332a, and 332b may include a first left dummy Y-switch block 331a disposed in an upper outer region of the first left upper cell area 110LTa in the first column C1, a first right dummy Y-switch block 331b disposed in an upper outer region of the first right upper cell area 110RTa in the second column C2, a second left dummy Y-switch block 332a disposed in a lower outer region of the second left lower cell area 110LBb in the first column C1, and a second right dummy Y-switch block 332b disposed in a lower outer region of the second right lower cell area 110RBb in the second column C2. Each of the dummy Y-switch blocks 331a, 331b, 332a, and 332b may include a plurality of dummy Y-switches DYS aligned and disposed in the first direction X. In an embodiment, the dummy Y-switches DYS may include dummy Y-transistors. In an embodiment, the dummy Y-switches DYS may be electrically connected to the inner Y-lines 32a and 32b. The dummy Y-switches DYS may be electrically floated. In another embodiment, the dummy Y-switches DYS may not be electrically connected to the inner Y-lines 32a and 32b. The auxiliary Y-switches YS may provide a voltage or a current to the outer Y-lines 31a and 31b. The dummy Y-switches DYS may not provide a voltage or a current to the inner Y-lines 32a and 32b.

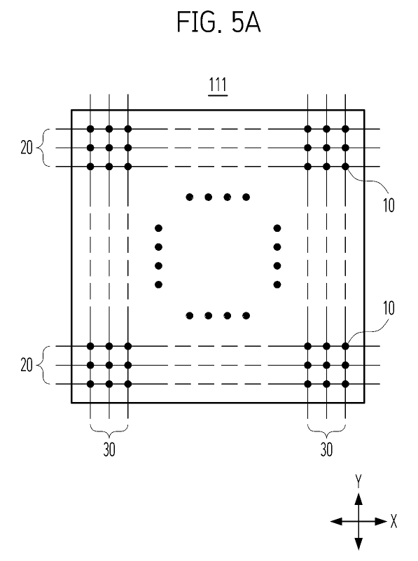

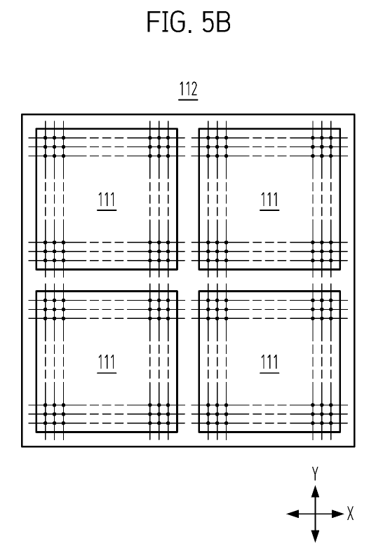

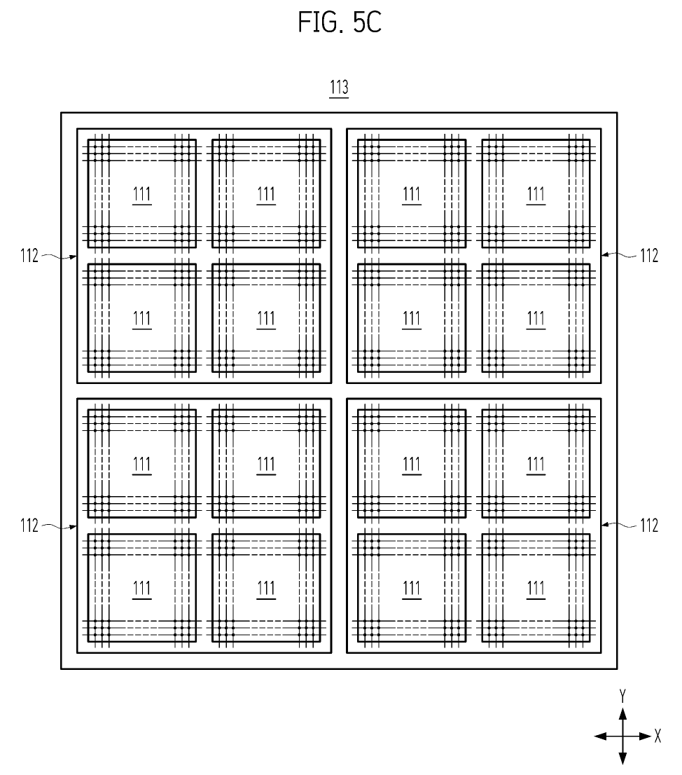

FIGS. 5A-5C are block diagrams schematically illustrating a cell area 110 of FIG. 1 according to an embodiment of the present disclosure. Referring to FIG. 5A, the cell area 110 may include a cell tile 111. The cell tile 111 may include a plurality of cells 10 arranged in a matrix form at intersections of a plurality of X-lines 20 and a plurality of Y-lines 30. Referring to FIG. 5B, the cell area 110 may include a cell MAT (matrix) 112. The cell MAT 112 may include a plurality of cell tiles 111 arranged in a matrix form. For example, the cell area 110 may include cell MATs 112 disposed at intersections of two rows and two columns. Referring to FIG. 5C, the cell area 110 may include a cell block 113. The cell block 113 may include a plurality of cell MATs 112 arranged in a matrix form.

According to the embodiments of the present disclosure, some of the cells may receive current simultaneously or in common from two switches disposed on both sides. Therefore, cell selection or enablement may be stably performed.

According to the embodiments of the present disclosure, an overcurrent phenomenon that occurs when cells are disposed adjacent to both the local X-switches and the local Y-switches can be prevented.

According to the embodiments of the present disclosure, an undercurrent phenomenon that occurs when cells are disposed far apart from both the local X-switches and the local Y-switches can be prevented.

While the present invention has been described with respect to specific embodiments, it will be apparent to those skilled in the art that various changes and modifications may be made without departing from the technical concepts and scope of the disclosure as defined in the following claims. Furthermore, the embodiments may be combined to form additional embodiments.

What is claimed is:

1. A semiconductor device comprising:
a local X-switch block;
a first auxiliary X-switch block, aligned with and overlapping the local X-switch block in a first direction, disposed on a first row;
a plurality of first cell areas, aligned with each other in the first direction, disposed on the first row between the local X-switch block and the first auxiliary X-switch block; and
first X-lines extending from the local X-switch block to cross the plurality of first cell areas in the first direction,
wherein the local X-switch block includes a plurality of local X-switches aligned with each other in a second direction, which is perpendicular to the first direction,
wherein the first auxiliary X-switch block includes a first auxiliary X-switch, and
wherein the first X-lines include:
a first outer X-line electrically connected to the first auxiliary X-switch and a first one of the plurality of local X-switches; and
a first inner X-line electrically connected to a second one of the plurality of local X-switches and not electrically connected to the first auxiliary X-switch.

2. The semiconductor device of claim 1, further comprising:
a second auxiliary X-switch block, aligned with and overlapping the local X-switch block in the first direction, disposed on a second row;
a plurality of second cell areas, aligned with each other in the first direction, disposed on the second row between the local X-switch block and the second auxiliary X-switch block; and
second X-lines extending from the local X-switch block to cross the plurality of second cell areas in the first direction are,
wherein the first auxiliary X-switch block and the second auxiliary switch block are aligned with each other in the second direction,
wherein the second auxiliary X-switch block includes a second auxiliary X-switch, and
wherein the second X-lines include:
a second outer X-line electrically connected to the second auxiliary X-switch and a third one of the plurality of local X-switches; and
a second inner X-line electrically connected to a fourth one of the plurality of local X-switches and not electrically connected to the second auxiliary X-switch.

3. The semiconductor device of claim 2, wherein:
the first row and the second row are parallel to each other in the first direction and adjacent to each other in the second direction,
the first outer X-line crosses upper regions of the plurality of first cell areas in the first direction,
the first inner X-line crosses lower regions of the plurality of first cell areas in the first direction,
the second outer X-line crosses lower regions of the plurality of second cell areas in the first direction, and
the second inner X-line crosses upper regions of the plurality of second cell areas in the first direction.

4. The semiconductor device of claim 2, further comprising:
a first dummy X-switch block disposed on the first row,
wherein:
the first dummy X-switch block is aligned with the local X-switch block in the first direction,
the first dummy X-switch block is aligned with and adjacent to the first auxiliary X-switch block in the second direction, and
wherein the first dummy X-switch block includes a first dummy X-switch.

5. The semiconductor device of claim 4, further comprising:
a second dummy X-switch block disposed on the second row,
wherein:
the second dummy X-switch block is aligned with the local X-switch block in the first direction,
the second dummy X-switch block is aligned with and adjacent to the second auxiliary X-switch block in the second direction, and
the second dummy X-switch block includes a second dummy X-switch.

6. The semiconductor device of claim 5,
wherein the first dummy X-switch block and the second dummy X-switch block, aligned with each other in the first direction, are disposed between the first auxiliary X-switch block and the second auxiliary X-switch block.

7. The semiconductor device of claim 5, wherein:
the first inner X-line is electrically connected to the first dummy X-switch, and
the second inner X-line is electrically connected to the second dummy X-switch.

8. The semiconductor device of claim 2, further comprising:
a first local Y-switch block disposed between a first one of the plurality of first cell areas on the first row and a first one of the plurality of second cell areas on the second row in the second direction; and
a first inner Y-line crossing the first one of the plurality of first cell areas and the first one of the plurality of second cell areas in the second direction from the first local Y-switch block.

9. The semiconductor device of claim 8,
wherein the first one of the plurality of first cell areas on the first row and the first one of the plurality of second cell areas on the second row are aligned with and adjacent to each other in the second direction.

10. The semiconductor device of claim 8, further comprising:
a first auxiliary Y-switch block disposed between a second one of the plurality of first cell areas on the first row and a second one of the plurality of second cell areas on the second row, wherein the first auxiliary Y-switch block overlaps and is aligned with the first local Y-switch block in the first direction; and
a first outer Y-line crossing the second one of the plurality of first cell areas and the second one of the plurality of second cell areas in the second direction from the first auxiliary Y-switch block.

11. The semiconductor device of claim 10,
wherein the second one of the plurality of first cell areas on the first row and the second one of the plurality of second cell areas on the second row are aligned and adjacent to each other in the second direction.

12. The semiconductor device of claim 10, wherein:
the first local Y-switch block includes a plurality of first local Y-switches aligned with each other in the first direction,
the first auxiliary Y-switch block includes a first auxiliary Y-switch,
the first outer Y-line is electrically connected to a first one of the first local Y-switches and the first auxiliary Y-switch, and
the first inner Y-line is electrically connected to a second one of the first local Y-switches and is not electrically connected to the first auxiliary Y-switch.

13. The semiconductor device of claim 12, further comprising:
a first dummy Y-switch block disposed between the second one of the plurality of first cell areas and the second one of the plurality of second cell areas,
wherein the first dummy Y-switch block is aligned with and adjacent to the first auxiliary Y-switch block in the first direction.

14. The semiconductor device of claim 2, wherein:
an upper area of the local X-switch block, the first cell areas, and the first auxiliary X-switch area are aligned on the first row, and
a lower area of the local X-switch block, the second cell areas, and the second auxiliary X-switch area are aligned on the second row.

15. The semiconductor device of claim 1,
wherein an occupied area of the first auxiliary X-switch block is smaller than an occupied area of the local X-switch block.

16. A semiconductor device comprising:
a local Y-switch block;
a first auxiliary Y-switch block, aligned with and overlapping a left area of the local Y-switch block in a vertical direction, arranged in a first column;
a plurality of first cell areas, aligned with each other in the vertical direction, arranged in the first column between the local Y-switch block and the first auxiliary Y-switch block; and
first Y-lines extending from the local Y-switch block to cross the plurality of first cell areas in the vertical direction,
wherein the local Y-switch block includes a plurality of local Y-switches aligned in a horizontal direction perpendicular to the vertical direction,
wherein the first auxiliary Y-switch block includes a first auxiliary Y-switch, and
wherein the first Y-lines include:
a first outer Y-line electrically connected to the first auxiliary Y-switch and a first one of the plurality of local Y-switches; and
a first inner Y-line electrically connected to a second one of the plurality of local Y-switches and not electrically connected to the first auxiliary Y-switch.

17. A semiconductor device comprising:
a plurality of cell areas arranged in a matrix form, wherein the matrix form includes a plurality of rows and a plurality of columns;
a first local switch block disposed between first cell areas among the plurality of cell areas in a first direction, wherein the first local switch block has a segment shape extending in a second direction;
a second local switch block disposed between second cell areas among the plurality of cell areas in the second direction, wherein the second local switch block has a segment shape extending in the first direction;
a first auxiliary switch block disposed between third cell areas among the plurality of cell areas in the first direction, wherein the first auxiliary switch block is aligned with the first local switch block in the second direction; and
a second auxiliary switch block disposed between fourth cell areas among the plurality of cell areas in the second direction, wherein the second auxiliary switch block is aligned with the second local switch block in the first direction,
wherein:
the first direction and the second direction are perpendicular to each other,
the first local switch block completely overlaps the first cell areas in the first direction,
the second local switch block completely overlaps the second cell areas in the second direction,
the first auxiliary switch block partially overlaps the third cell areas in the first direction, and
the second auxiliary switch block partially overlaps the fourth cell areas in the second direction.

18. The semiconductor device of claim 17,
wherein the first cell areas include upper first cell areas disposed on the first row and lower first cell areas disposed on the second row,
wherein an upper area of the first local switch block is aligned with the upper first cell areas in the first direction,
wherein a lower region of the first local switch block is aligned with the lower first cell areas in the first direction,
wherein the third cell areas include upper third cell areas disposed on the first row and lower third cell areas disposed on the second row, and
wherein the first auxiliary switch block includes:
an upper first auxiliary switch block aligned with the upper third cell areas in the first direction; and
a lower first auxiliary switch block aligned with the lower third cell areas in the first direction.

19. The semiconductor device of claim 17,
wherein the second cell areas include left second cell areas disposed on a first column and right second cell areas disposed on a second column,
wherein a left region of the second local switch block is aligned with the left second cell areas in the second direction,
wherein a right region of the second local switch block is aligned with the right second cell areas in the second direction,
wherein the fourth cell areas include left fourth cell areas disposed on the first column and right fourth cell areas disposed on the second column, and
wherein the second auxiliary switch block includes:
a left second auxiliary switch block aligned with the left fourth cell areas in the second direction; and
a right second auxiliary switch block aligned with the right fourth cell areas in the second direction.

20. The semiconductor device of claim 17, further comprising:
a first dummy switch block disposed between the third cell areas in the first direction, wherein the first dummy switch block is aligned with the first auxiliary switch block in the second direction; and
a second dummy switch block disposed between the fourth cell areas in the second direction, wherein the second dummy switch block is aligned with the second auxiliary switch block in the first direction.
